(19) United States
(12) Patent Application Publication
(10) Pub. No.: US 2019/0356246 A1
(43) Pub. Date: Nov. 21, 2019

(54) VIBRATION POWERED GENERATOR

(71) Applicant: TOHOKU STEEL Co., Ltd., Shibata-gun, Miyagi (JP)

(72) Inventors: Ryuichi ONODERA, Shibata-gun (JP); Tsuyoki TAYAMA, Shibata-gun (JP); Takenobu SATO, Shibata-gun (JP); Takashi EBATA, Shibata-gun (JP); Fumio NARITA, Sendai-shi (JP)

(73) Assignee: TOHOKU STEEL Co., Ltd., Shibata-gun, Miyagi (JP)

(21) Appl. No.: 16/474,122

(22) PCT Filed: Dec. 20, 2017
(86) PCT No.: PCT/JP2017/045635

§ 371 Date: Jun. 27, 2019

(30) Foreign Application Priority Data
Dec. 27, 2016 (JP) 2016-254319

(51) Int. Cl. H02N 2/18; H01L 41/12; G01R 33/18

(52) U.S. Cl. CPC H02N 2/188; G01R 33/18; H01L 41/125

(57) ABSTRACT

A vibration powered generator capable of vibrating at a plurality of resonance frequencies to generate electric power with a simpler structure is provided. A vibration powered generator has an elongated magnetostrictive material having one end attached to a vibrating body, in which the magnetostrictive material vibrates due to vibration of the vibrating body whereby the vibration powered generator generates electric power with the aid of an inverse magnetostrictive effect of the magnetostrictive material. A cross-sectional shape vertical to a longitudinal direction of the magnetostrictive material has an asymmetrical shape with respect to a straight line extending along a vibration direction thereof due to vibration of the vibrating body.

### FIELD OF THE INVENTION

The present invention relates to a vibration powered generator.

### DESCRIPTION OF RELATED ART

Conventionally, a vibration powered generator that vibrates at a plurality of resonance frequencies to generate electric power has been developed in order to obtain electrical energy from vibration in a frequency range as wide as possible. An example of such a vibration powered generator which uses a magnetostrictive material is a power generator (for example, see Patent Literature 1) which includes a power generation element formed by winding a coil 15 around a magnetostrictive rod formed of a magnetostrictive material, an elastic rod provided at one end of the power generation element, and a plurality of spindles provided in the elastic rod and in which the other end of the power generation element is fixed to generate electric power by vibrating at a plurality of resonance frequencies. Another example is a magnetostrictive vibration powered generator (for example, see Patent Literature 2) which is a power generating vibration system in which a vibration system includes a plurality of partial vibration systems arranged serially in a vibration transmission direction, at least one partial vibration system includes a power generation element having a magnetostrictive material, and the resonance frequencies of the partial vibration systems are different.

### CITATION LIST

Patent Literature 1: JP-A-2014-018006
Patent Literature 2: JP-A-2015-006064

### SUMMARY OF THE INVENTION

However, the power generators disclosed in Patent Literatures 1 and 2 need to have a plurality of spindles and a plurality of partial vibration systems in correspondence to a plurality of resonance frequencies, and there is a problem that the structure becomes complex.

The present invention has been made in view of the above-described problems, and an object thereof is to provide a vibration powered generator capable of vibrating at a plurality of resonance frequencies to generate electric power with a simpler structure.

In order to attain the object, a vibration powered generator according to the present invention has an elongated magnetostrictive material having one end attached to a vibrating body, in which the magnetostrictive material vibrates due to vibration of the vibrating body whereby the vibration powered generator generates electric power with the aid of an inverse magnetostrictive effect of the magnetostrictive material, wherein a cross-sectional shape vertical to a longitudinal direction of the magnetostrictive material has an asymmetrical shape with respect to a straight line extending along a vibration direction thereof due to vibration of the vibrating body.

In the vibration powered generator according to the present invention, since the cross-sectional shape vertical to the longitudinal direction of the magnetostrictive material has an asymmetrical shape with respect to the straight line extending along the vibration direction thereof due to vibration of the vibrating body, it is possible to vibrate at a plurality of resonance frequencies according to the cross-sectional shape to generate electric power. For example, since the magnetostrictive material has a cross-sectional shape vertical to the longitudinal direction such that a largest width and a largest thickness are different, and a largest width direction and a largest thickness direction are inclined with respect to the vibration direction, the vibration powered generator can vibrate at two different resonance frequencies of vibration in the width direction and vibration in the thickness direction to generate electric power. In this way, the vibration powered generator according to the present invention can vibrate at a plurality of resonance frequencies to generate electric power with a simpler structure in which the cross-sectional shape and the angle with respect to the vibration direction of the vibrating body are adjusted deliberately.

In the vibration powered generator according to the present invention, the cross-sectional shape vertical to the longitudinal direction of the magnetostrictive material may have the asymmetrical shape with respect to the straight line extending along the vibration direction of the magnetostrictive material in a partial segment in the longitudinal direction or in the entire length of the magnetostrictive material. Moreover, the vibration powered generator according to the present invention may have an elongated beam member having one end 12a fixed to the vibrating body, the magnetostrictive material may form a portion in the longitudinal direction of the beam member, and the beam member may be made up of the magnetostrictive material only. Furthermore, the vibration powered generator according to the present invention may have a spindle attached to the other end of the magnetostrictive material in order to increase the amplitude of the magnetostrictive material.

In the vibration powered generator according to the present invention, the cross-sectional shape vertical to the longitudinal direction of the magnetostrictive material may have an arbitrary shape (for example, an indefinite shape or a cylindrical shape) as long as the cross-sectional shape has an analysis support system with respect to the straight line extending along the vibration direction thereof. Although the vibrating body may be an arbitrary member as long as it vibrates, a vibration direction, a vibration frequency, or the like is preferably constant in order to generate electric power efficiently. The vibrating body is preferably an industrial machine such as a pump or a motor, for example.

In the vibration powered generator according to the present invention, the magnetostrictive material may be configured to rotate about an axis extending along the longitudinal direction in a state of being attached to the vibrating body. In this case, since the angle of the cross-sectional shape vertical to the longitudinal direction of the magnetostrictive material can be changed with respect to the vibration direction, it is possible to change the magnitude of vibration at respective resonance frequencies. Therefore, by rotating the magnetostrictive material according to the vibration frequency of the vibrating body, it is possible to generate electric power efficiently.

In the vibration powered generator according to the present invention, when the magnetostrictive material has a cross-sectional shape vertical such that a largest width and a largest thickness are different, an angle between the largest width direction and/or the largest thickness direction and the vibration direction may be changed in a state in which the magnetostrictive material is attached to the vibrating body. In this case, it is possible to change the magnitude of vibration at respective resonance frequencies according to the angle and adjust the power generation amount. In the vibration powered generator according to the present invention, the ratio of the largest width of the magnetostrictive material to the largest thickness may be changed in a state in which the magnetostrictive material is attached to the vibrating body. In this case, it is possible to change the respective resonance frequencies according to the ratio. Therefore, by changing the angle of the magnetostrictive material and the ratio of the largest width to the largest thickness according to the vibration frequency of the vibrating body, it is possible to generate electric power efficiently.

In the vibration powered generator according to the present invention, in a case in which the magnetostrictive material has a cross-sectional shape in which the largest width and the largest thickness are different, when the largest width of the magnetostrictive material is b and the largest thickness is h, a value of b/h may be between 2.5 and 5.0. In this case, since the difference between resonance frequencies increases, it is possible to perform power generation from vibration in a wider frequency range and enhance power generation efficiency.

In the vibration powered generator according to the present invention, the magnetostrictive material may have a shape in which the cross-sectional shape changes along the longitudinal direction. In this case, it is possible to adjust a deformation shape, an amplitude, and the like of the magnetostrictive material during vibration by changing the shape of the magnetostrictive material. Therefore, by narrowing a portion of the magnetostrictive material, for example, so that stress easily concentrate on the portion during vibration, it is possible to enhance power generation efficiency.

In the vibration powered generator according to the present invention, the magnetostrictive material is preferably formed of a Fe—Co-based alloy. In this case, the magnetostrictive material can be manufactured easily by applying rolling and heat treatment to a relatively inexpensive Fe—Co-based alloy. Moreover, since the processability of the magnetostrictive material is satisfactory and plastic processing such as cutting and bending is easy, it is possible to form the magnetostrictive material in an arbitrary shape easily.

In the vibration powered generator according to the present invention, a composite material obtained by bonding a magnetostrictive material and a soft magnetic material may be used instead of the magnetostrictive material. In this case, the composite material vibrates due to vibration of the vibrating body whereby it is possible to generate electric power with the aid of an inverse magnetostrictive effect of the magnetostrictive material in the composite material. Moreover, it is possible to change magnetization of the soft magnetic material in the composite material with the aid of change in magnetization due to the inverse magnetostrictive effect while generating electric power with the aid of the inverse magnetostrictive effect of the magnetostrictive material. Due to the change in magnetization of the soft magnetic material, it is possible to enhance the vibration-assisted power generation performance due to the inverse magnetostrictive effect better than the case of using the inverse magnetostrictive effect of the magnetostrictive material only.

When the composite material is used, the magnetostrictive material in the composite material is preferably formed of a Fe—Co-based alloy. The soft magnetic material in the composite material may be an arbitrary material, and for example, may be formed of malleable iron, a Fe—Ni-based alloy represented by PB permalloy, silicon steel, and electromagnetic stainless steel. Moreover, the soft magnetic material preferably has a coercive force of 8 A/cm or smaller and particularly preferably 3 A/cm. Furthermore, the soft magnetic material may be formed of a magnetostrictive material having a magnetostrictive constant of a different sign from the magnetostrictive constant of the magnetostrictive material. As examples of these materials, any one of the soft magnetic material and the magnetostrictive material may be formed of a Fe—Co-based alloy having a positive magnetostrictive constant, and the other may be formed of an alloy made up of Ni and 0 to 20 mass % of Fe having a negative magnetostrictive constant. In this case, it is possible to use inverse magnetostrictive effect resulting from compressive stress and tensile stress generated simultaneously by vibration and further enhance power generation performance.

When the composite material is used, the soft magnetic material and the magnetostrictive material may be bonded by an arbitrary method such as thermal diffusion joining, hot rolling, hot drawing, adhesive, or welding. Particularly, when the materials are bonded by thermal diffusion joining, hot rolling, or hot drawing, due to residual stress after the materials are bonded under high temperature and are cooled, displacement of a domain wall of the magnetostrictive material is facilitated and change in magnetization is accelerated. Therefore, it is possible to further enhance power generation performance with the aid of an inverse magnetostrictive effect. Moreover, the soft magnetic material and the magnetostrictive material may be bonded with a load applied thereto. In this case, due to residual stress when the load is released after bonding is realized, displacement of a domain wall of the magnetostrictive material is facilitated and change in magnetization is accelerated. Therefore, it is possible to further enhance power generation performance with the aid of an inverse magnetostrictive effect.

According to the present invention, it is possible to provide a vibration powered generator capable of vibrating at a plurality of resonance frequencies to generate electric power with a simpler structure.

### BRIEF DESCRIPTION OF THE DRAWINGS

FIG. 1 is a perspective view illustrating a vibration powered generator according to an embodiment of the present invention.

FIG. 2 is a right side view of the vibration powered generator illustrated in FIG. 1.

FIG. 3 includes (a) a graph illustrating a relation between a vibration frequency and a power generation amount of a magnetostrictive material and (b) an enlarged graph near the higher resonance frequency in (a), when an inclination angle of the magnetostrictive material with respect to a vibration direction of the vibration powered generator illustrated in FIG. 1 is changed.

FIG. 4 includes (a) a graph illustrating a relation between a vibration frequency and a power generation amount of a magnetostrictive material when a ratio b/h of a length b in a width direction of the magnetostrictive material and a length h in a thickness direction, (b) a graph illustrating a change in difference (Δf) between the higher resonance frequency and the smaller resonance frequency with respect to b/h for respective calculation models, and (c) a graph illustrating measurement results of the power generation amount for a plurality of vibration frequencies for b/h=3.3 and 2.5, in the vibration powered generator illustrated in FIG. 1.

FIG. 5 includes (a) a perspective view illustrating a modified embodiment in which a magnetostrictive material has a narrow-width processed portion, (b) a graph illustrating a power generation amount in the case of (a) and a power generation amount when a magnetostrictive material is formed of a rectangular planar simple beam without a processed portion, and (c) a perspective view illustrating a modified embodiment in which a magnetostrictive material has a bent shape, in the vibration powered generator according to the embodiment of the present invention.

### DETAILED DESCRIPTION OF THE INVENTION

Embodiments of the present invention will be described with reference to the drawings.

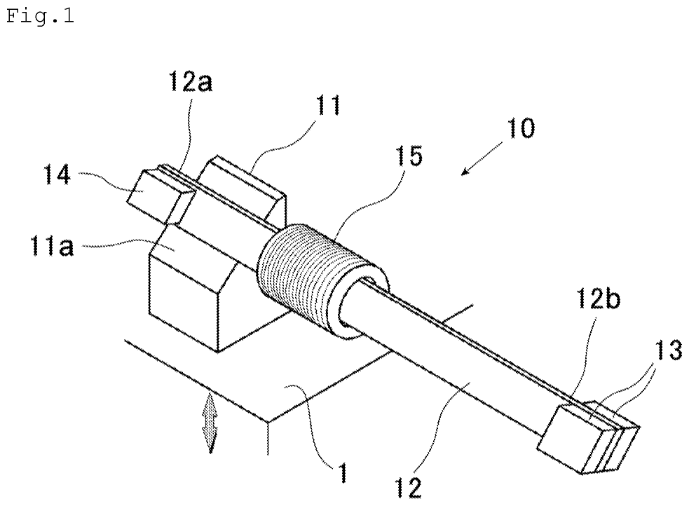

FIGS. 1 to 5 illustrate a vibration powered generator according to an embodiment of the present invention.

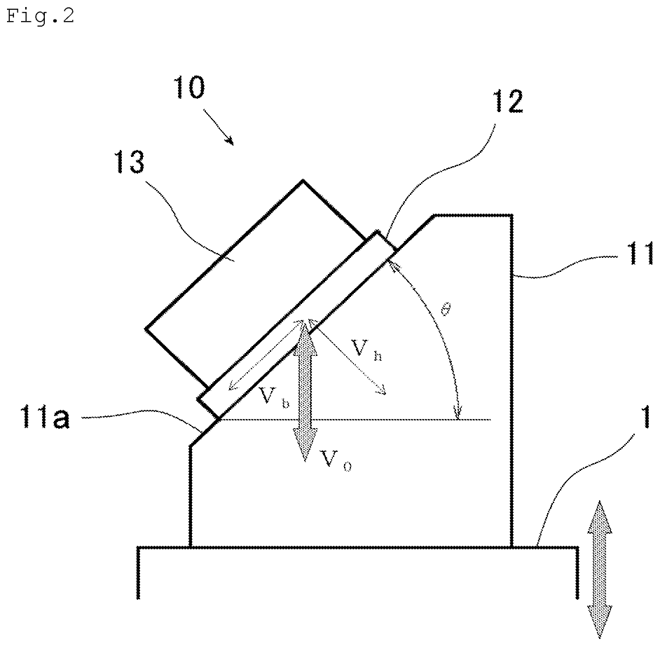

As illustrated in FIGS. 1 and 2, a vibration powered generator 10 is used in a state of being attached to a vibrating body 1 and includes a support 11, a magnetostrictive material 12, a spindle 13, a magnet 14, and a coil 15.

The support 11 is provided to be attachable to the vibrating body 1 and has a flat attachment surface 11a inclined with respect to a vibration direction of the vibrating body 1 when attached to the vibrating body 1.

The magnetostrictive material 12 is formed of a Fe—Co-based alloy and has an elongated rectangular planar shape. A cross-section vertical to a longitudinal direction of the magnetostrictive material 12 has a rectangular shape such that a largest width which is the length in the width direction is different from a largest thickness which is the length in the thickness direction.

The magnetostrictive material 12 has one surface of one end 12a thereof being fixed in close content with an attachment surface 11a of the support 11. Due to this, the magnetostrictive material 12 has one end 12a attached to the vibrating body 1 with the support 11 disposed therebetween. Moreover, as illustrated in FIG. 2, the magnetostrictive material 12 is attached so that the width direction (the largest width direction) and the thickness direction (the largest thickness direction) are inclined with respect to a vibration direction thereof due to vibration of the vibrating body 1. Moreover, a cross-sectional shape vertical to the longitudinal direction of the magnetostrictive material 12 has an asymmetrical shape with respect to a straight line along the vibration direction thereof due to vibration of the vibrating body 1. The surface of the magnetostrictive material 12 is a surface that is flat in the width direction and the longitudinal direction of the magnetostrictive material 12.

The spindle 13 is attached to the other end 12b of the magnetostrictive material 12. In a specific example illustrated in FIG. 1, the spindle 13 is attached to both surfaces of the magnetostrictive material 12. In a specific example illustrated in FIG. 2, the spindle 13 is attached to one surface of the magnetostrictive material 12. The magnet 14 is attached to one end 12a of the magnetostrictive material 12 so that a bias magnetic field can be applied to the magnetostrictive material 12. The coil 15 has the magnetostrictive material 12 having passed to the inner side thereof and is disposed close to the other end 12b of the magnetostrictive material 1 at which the magnetostrictive material 12 is attached to the support 11.

The vibration powered generator 10 is configured such that the magnetostrictive material 12 forms a cantilevered beam and the side of the other end 12b of the magnetostrictive material 12 vibrates due to vibration of the vibrating body 1. In this way, the vibration powered generator 10 is configured so as to generate electric power due to an inverse magnetostrictive effect of the magnetostrictive material 12 when the magnetostrictive material 12 vibrates.

Next, an operation will be described.

The vibration powered generator 10 is used by being installed in the vibrating body 1 such as an industrial machine that vibrates in a certain direction. A cross-section of the vibration powered generator 10 vertical to the longitudinal direction of the magnetostrictive material 12 has a rectangular shape and the vibration powered generator 10 is attached so as to be inclined in the width direction (the largest width direction) and the thickness direction (the largest thickness direction) with respect to the vibration direction thereof. Therefore, the vibration powered generator 10 can vibrate at two different resonance frequencies of vibration in the width direction and vibration in the thickness direction to generate electric power. For example, as illustrated in FIG. 2, when an angle between a horizontal surface and the attachment surface 11a (the surface of the magnetostrictive material 12) of the support 11 of the vibration powered generator 10 is θ and the magnetostrictive material 12 vibrates with an amplitude of V₀ due to vibration of the vibrating body 1, the amplitude of vibration in the width direction (the largest width direction) of the magnetostrictive material 12 is Vb=V₀ sin θ and the amplitude of vibration in the thickness direction (the largest thickness direction) of the magnetostrictive material 12 is Vh=V₀ cos θ. The vibration powered generator 10 can vibrate at two different resonance frequencies to generate electric power due to vibration of the magnetostrictive material 12 in two directions.

As described above, the vibration powered generator 10 can vibrate at a plurality of resonance frequencies to generate electric power with a simpler structure in which the cross-sectional shape and the angle with respect to the vibration direction of the vibrating body 1 are adjusted deliberately. In the vibration powered generator 10, the values of respective resonance frequencies and the magnitudes of vibration at the respective resonance frequencies are determined depending on the ratio of the length in the width direction of the magnetostrictive material 12 and the length in the thickness direction and the inclination angles of the width direction and the thickness direction with respect to the vibration direction of the magnetostrictive material 12.

Since the vibration powered generator 10 has the spindle 13 attached to the other end 12b of the magnetostrictive material 12, the amplitude of the magnetostrictive material 12 increases and satisfactory power generation efficiency is obtained. Since the magnetostrictive material 12 is formed of a Fe—Co-based alloy, the vibration powered generator 10 can be manufactured easily by applying rolling and heat treatment to a relatively inexpensive Fe—Co-based alloy. Moreover, since the processability of the magnetostrictive material 12 is satisfactory and plastic processing such as cutting and bending is easy, it is possible to form the magnetostrictive material 12 in a desired shape easily.

[Relation between vibration frequency and power generation amount when inclination angle of magnetostrictive material 12 and cross-sectional shape of magnetostrictive material are changed]

As a calculation model, the relation between a vibration frequency and a power generation amount of the magnetostrictive material 12 were obtained by calculation using the vibration powered generator 10 illustrated in FIG. 2. In the vibration powered generator 10 illustrated in FIG. 2, the spindle 13 is attached to one surface of the magnetostrictive material 12 and the weight thereof was 20 g. Moreover, the length (L) in an extension direction of the magnetostrictive material 12 was 40 times (that is, L=40×b) the length (b) in the width direction.

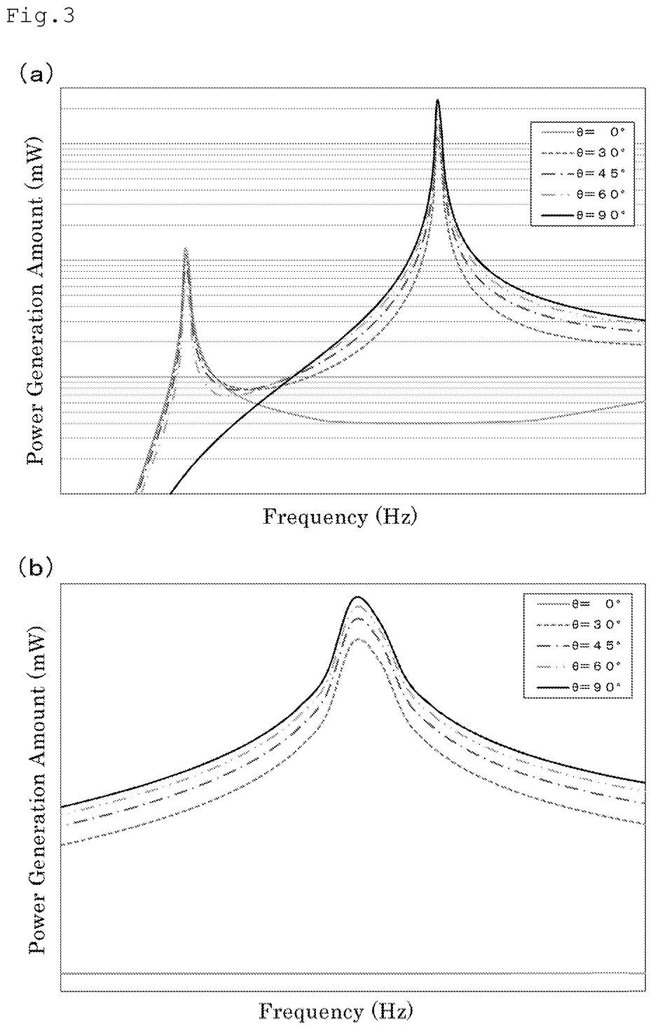

First, calculation was performed for a case in which the ratio (b/h) of the length (b) in the width direction of the magnetostrictive material 12 to the length (h) in the thickness direction was fixed and the inclination angle of the magnetostrictive material 12 with respect to the vibration direction was changed. Here, θ (corresponding to the inclination angle of the thickness direction of the magnetostrictive material 12 with respect to the vibration direction) in FIG. 2 was used as the inclination angle of the magnetostrictive material 12 with respect to the vibration direction. Moreover, b/h was 3.3. The calculation results for this case are illustrated in FIGS. 3(a) and 3(b).

As illustrated in FIG. 3(a), only one peak power generation amount and one resonance frequency were found for θ=0° and 90°, whereas two peak power generation amounts and two resonance frequencies were found for 0°<θ<90°. Moreover, as illustrated in FIG. 3(b), it was found that the power generation amount increased when θ was increased at a larger resonance frequency. Similarly, it was found that the power generation amount increased when θ was decreased at a smaller resonance frequency. From these results, it was understood that two resonance frequencies are obtained when the magnetostrictive material 12 was inclined with respect to the vibration direction, and the power generation amounts at the respective resonance frequencies can be adjusted by changing the inclination angle (θ in FIG. 2).

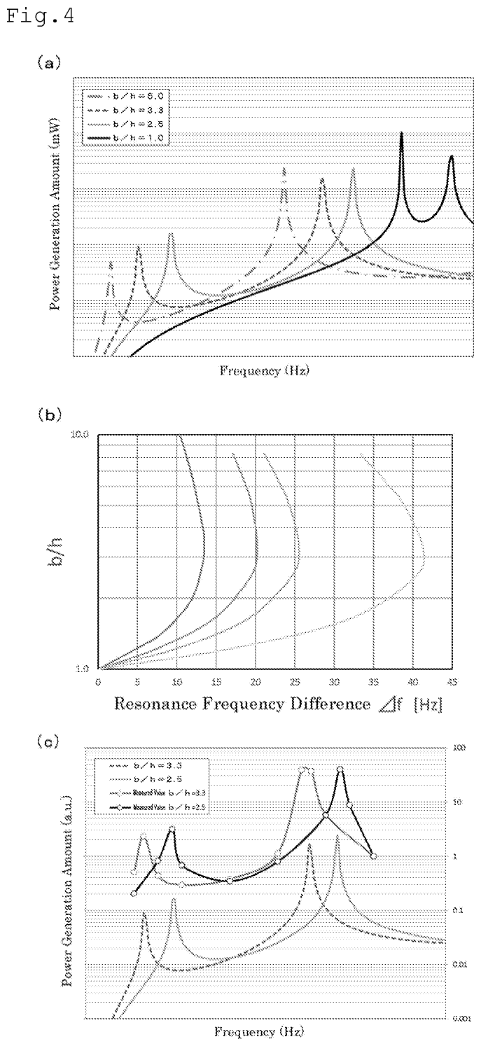

Subsequently, calculation was performed for a case in which the inclination angle (θ in FIG. 2) of the magnetostrictive material 12 with respect to the vibration direction was fixed and the ratio (b/h) of the length (b) in the width direction of the magnetostrictive material 12 to the length (h) in the thickness direction was changed. Here, θ was 45°. The calculation results for this case are illustrated in FIG. 4(a). As illustrated in FIG. 4(a), it was found that, when b/h was increased, the larger resonance frequency and the smaller resonance frequency decreased. Moreover, it was found that, when b/h was increased, a difference (Δf) between the larger resonance frequency and the smaller resonance frequency changed. In FIG. 4(a), two resonance frequencies were obtained for b/h=1.0 (a cross-sectional shape vertical to the longitudinal direction of the magnetostrictive material 12 is square). This is because the spindle 13 was attached to one surface of the magnetostrictive material 12.

Subsequently, in order to examine a change in the difference (Δf) between the larger resonance frequency and the smaller resonance frequency, a change in Δf with respect to b/h was obtained for a plurality of calculation models in which the weight of the spindle 13 and the length (L) of the magnetostrictive material 12 were changed. The calculation results are illustrated in FIG. 4(b) for respective calculation models. As illustrated in FIG. 4(b), in any calculation model, it was found that Δf increased when b/h was between 2.5 and 5.0 and Δf reaches the largest when b/h was around 3.

Subsequently, the vibration powered generator 10 illustrated in FIG. 1 was manufactured, and power generation amounts at a plurality of vibration frequencies were measured for b/h of 3.3 and 2.5. Here, θ was 45° and L was 40×b. The measurement results for this case are illustrated in FIG. 4(c). In FIG. 4(c), the measurement values are normalized by power generation amounts at a measured highest frequency. FIG. 4(c) also illustrates the calculation results for b/h of 3.3 and 2.5 illustrated in FIG. 4(a) for comparison. As illustrated in FIG. 4(c), it was found that the measurement values for b/h of 3.3 and 2.5 showed substantially the same trend as the calculation results in terms of the position of a resonance frequency and the change in power generation amount with respect to the vibration frequency.

From the results of FIGS. 3 and 4, it can be understood that the vibration powered generator 10 can adjust the power generation amounts at the respective resonance frequencies and the positions of the resonance frequencies by changing the inclination angle (θ in FIG. 2) of the magnetostrictive material 12 and the ratio (b/h) of the largest width (b) and the largest thickness (h) and can perform power generation efficiently by changing the inclination angle and the b/h of the magnetostrictive material 12 according to a vibration frequency or the like of the vibrating body 1.

In the vibration powered generator 10, the cross-sectional shape vertical to the longitudinal direction of the magnetostrictive material 12 is not limited to a rectangular shape but may be an elliptical shape. In this case, it is possible to adjust the positions of the resonance frequencies by changing the ratio of the long-axis length to the short-axis length. Therefore, it is possible to perform power generation efficiently by changing the inclination angle of the magnetostrictive material 12 and the ratio of the long-axis length to the short-axis length according to a vibration frequency or the like of the vibrating body 1.

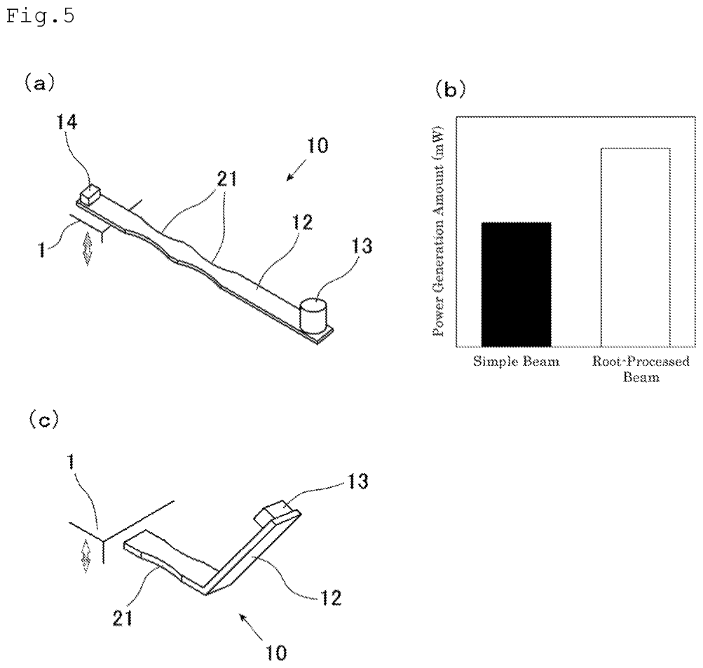

Since the magnetostrictive material 12 of the vibration powered generator 10 has satisfactory processability, the magnetostrictive material 12 can be processed in various shapes. For example, as illustrated in FIG. 5(a), the cross-sectional shape vertical to the longitudinal direction of the magnetostrictive material 12 may have a shape that changes along the longitudinal direction. In an example illustrated in FIG. 5(a), the magnetostrictive material 12 has an elongated rectangular planar shape and has two processed portions 21 formed in a central portion in the longitudinal direction thereof and a portion (a root-side portion) closer to one end 12a than the central portion so that both lateral portions are cut in a circular arc form so that the width narrows. In this way, since stress easily concentrates on the processed portion 21 during vibration, it is possible to enhance power generation efficiency.

FIG. 5(b) illustrates calculation results of a power generation amount when all conditions other than the processed portion 21 remain the same for the vibration powered generator 10 which uses the magnetostrictive material 12 (a root-processed beam) with a shape having the processed portion 21 illustrated in FIG. 5(a) and the vibration powered generator 10 which uses the magnetostrictive material 12 formed of a rectangular planar simple beam without the processed portion 21. As illustrated in FIG. 5(b), it was found that the power generation amount increased due to the processed portion 21 having a narrow width, and the amount of increase reached approximately 60% depending on a condition.

As illustrated in FIG. 5(c), the magnetostrictive material 12 is not limited to a shape that extends straightly in the longitudinal direction but may have a shape which is bent halfway by bending. In this way, the vibration powered generator 10 can adjust a deformation shape, an amplitude, and the like of the magnetostrictive material 12 during vibration and enhance power generation efficiency by changing the shape of the magnetostrictive material 12 depending on various conditions such as vibration of the vibrating body 1.

The vibration powered generator 10 may be formed using a composite material obtained by bonding a magnetostrictive material and a soft magnetic material instead of using the magnetostrictive material 12. In this case, the composite material vibrates due to vibration of the vibrating body 1 whereby it is possible to generate electric power with the aid of an inverse magnetostrictive effect of the magnetostrictive material in the composite material. Moreover, it is possible to change magnetization of the soft magnetic material in the composite material with the aid of change in magnetization due to the inverse magnetostrictive effect while generating electric power with the aid of the inverse magnetostrictive effect of the magnetostrictive material. Due to the change in magnetization of the soft magnetic material, it is possible to enhance the vibration-assisted power generation performance due to the inverse magnetostrictive effect better than the case of using the inverse magnetostrictive effect of the magnetostrictive material only.

### REFERENCE SIGNS LIST

1: Vibrating body
10: Vibration powered generator
11: Support
11a: Attachment surface
12: Magnetostrictive material
12a: One end
12b: Other end
13: Spindle
14: Magnet
15: Coil
21: Processed portion

1. A vibration powered generator having an elongated magnetostrictive material having one end attached to a vibrating body, in which the magnetostrictive material vibrates due to vibration of the vibrating body whereby the vibration powered generator generates electric power with the aid of an inverse magnetostrictive effect of the magnetostrictive material, wherein
a cross-sectional shape vertical to a longitudinal direction of the magnetostrictive material has an asymmetrical shape with respect to a straight line extending along a vibration direction thereof due to vibration of the vibrating body.

2. The vibration powered generator according to claim 1, wherein the magnetostrictive material is configured to rotate about an axis extending along the longitudinal direction in a state of being attached to the vibrating body.

3. The vibration powered generator according to claim 1, wherein
the magnetostrictive material has a cross-sectional shape vertical to the longitudinal direction such that a largest width and a largest thickness are different, and a largest width direction and a largest thickness direction are inclined with respect to the vibration direction.

4. The vibration powered generator according to claim 3, wherein an angle between the largest width direction and/or the largest thickness direction and the vibration direction can be changed in a state in which the magnetostrictive material is attached to the vibrating body.

5. The vibration powered generator according to claim 3, wherein
a ratio of the largest width of the magnetostrictive material to the largest thickness can be changed in a state in which the magnetostrictive material is attached to the vibrating body.

6. The vibration powered generator according to claim 3, wherein
when the largest width of the magnetostrictive material is b and the largest thickness is h, a value of b/h is between 2.5 and 5.0.

7. The vibration powered generator according to claim 1, wherein
the magnetostrictive material has a shape in which the cross-sectional shape changes along the longitudinal direction.

8. The vibration powered generator according to claim 1, wherein
the magnetostrictive material is formed of a Fe—Co-based alloy.

9. The vibration powered generator according to claim 1, wherein
a composite material obtained by bonding a magnetostrictive material and a soft magnetic material is used instead of the magnetostrictive material.
